(19) United States
(12) Patent Application Publication
(10) Pub. No.: US 2024/0373603 A1
(43) Pub. Date: Nov. 7, 2024

(54) POWER CONVERSION DEVICE AND DRIVE DEVICE

(71) Applicant: NIDEC CORPORATION, Kyoto (JP)

(72) Inventor: Satoshi HIROTA, Kyoto (JP)

(21) Appl. No.: 18/686,434

(22) PCT Filed: Aug. 26, 2022
(86) PCT No.: PCT/JP2022/032205

§ 371 Date: Feb. 26, 2024

Related U.S. Application Data
(60) Provisional application No. 63/238,472, filed on Aug. 30, 2021.

(51) Int. Cl. H05K 7/20; H02M 7/00

(52) U.S. Cl. CPC H05K 7/20927; H02M 7/003

(57) ABSTRACT

A power conversion device includes a first module that is a heating element, a second module that is a heating element having a larger calorific value than the first module, a housing having an accommodation space for accommodating the first module and the second module, and a refrigerant flow path through which a refrigerant flows. The housing has a lid that covers the accommodation space. The refrigerant flow path includes a first flow path portion that is disposed outside the accommodation space and cools the first module via the lid, and a second flow path portion that is disposed inside the accommodation space and cools the second module.

### CROSS-REFERENCE TO RELATED APPLICATIONS

This is the U.S. national stage of application No. PCT/JP2022/032205, filed on Aug. 26, 2022, and priority under 35 U.S.C. § 119 (a) and 35 U.S.C. § 365 (b) is claimed from U.S. Patent Application No. 63/238,472, filed on Aug. 30, 2021, the contents of which are incorporated herein by reference.

### FIELD OF THE INVENTION

The present invention relates to a power conversion device and a drive device.

### BACKGROUND

A power conversion device has been developed as a control device for a motor of an electric vehicle or a hybrid electric vehicle. Since the power conversion device includes heat generating components, it is required to appropriately cool these components. A power conversion device in which a switch unit in a housing is cooled by disposing a cold plate provided with a cooling path through which a coolant flows in the housing has been known.

In the conventional power conversion device, the entire cooling flow path is disposed in the housing. For this reason, when various parts in the housing are to be cooled, there is a problem that the cooling flow path also becomes complicated in the housing and the manufacturing cost of the device increases.

### SUMMARY

One aspect of an exemplary power conversion device of the present invention includes: a first module that is a heating element; a second module that is a heating element having a larger calorific value than the first module; a housing having an accommodation space for accommodating the first module and the second module; and a refrigerant flow path through which a refrigerant flows. The housing includes a lid that covers the accommodation space. The refrigerant flow path includes a first flow path portion that is disposed outside the accommodation space and cools the first module via the lid, and a second flow path portion that is disposed inside the accommodation space and cools the second module.

One aspect of an exemplary drive device of the present invention includes the above-described power conversion device and a rotary electric machine connected to the power conversion device.

The above and other elements, features, steps, characteristics and advantages of the present disclosure will become more apparent from the following detailed description of the preferred embodiments with reference to the attached drawings.

### BRIEF DESCRIPTION OF THE DRAWINGS

FIG. 1 is a perspective view of a drive device on which a power conversion device according to an embodiment is mounted;

FIG. 2 is a plan view of the power conversion device according to an embodiment; and

FIG. 3 is a schematic cross-sectional view of the power conversion device according to an embodiment.

### DETAILED DESCRIPTION

A power conversion device 3 according to an embodiment of the present invention will be described below with reference to the drawings. In the following drawings, each structure may be different in contraction scale, number, or the like from an actual structure for easy understanding.

Description below will be made with a direction of gravity being specified based on a positional relationship in a case where the power conversion device 3 is mounted in a vehicle positioned on a horizontal road surface. However, the posture of the power conversion device 3 in the present specification is an example, and does not limit the posture in which the power conversion device 3 is actually attached.

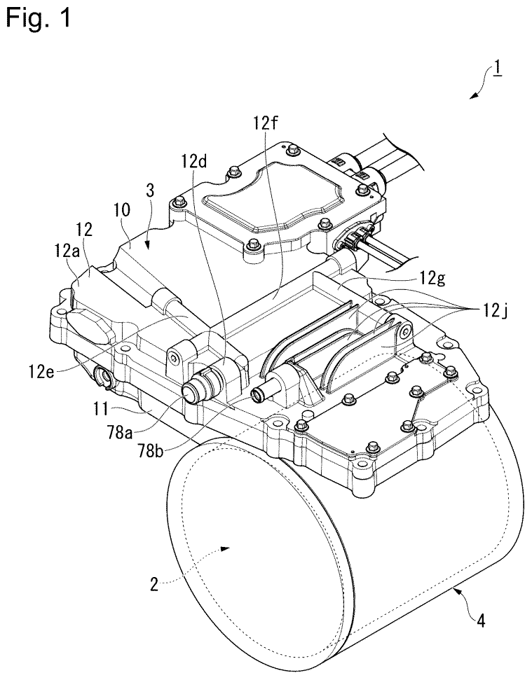

FIG. 1 is a perspective view of a drive device 1 on which the power conversion device 3 is mounted.

The drive device 1 includes the power conversion device 3, a rotary electric machine 2, and a rotary electric machine housing 4. Note that the drive device 1 may further include a speed reducer. In this case, the speed reducer is connected to a rotor of the rotary electric machine 2 to decelerate and output the rotation of the rotary electric machine 2.

The drive device 1 of the present embodiment is mounted on a vehicle using a rotary electric machine as a power source, such as a hybrid electric vehicle (HEV), a plug-in hybrid electric vehicle (PHV), or an electric vehicle (EV), and is used as the power source.

The rotary electric machine housing 4 accommodates the rotary electric machine 2 therein. The power conversion device 3 is fixed to the outer surface of the rotary electric machine housing 4. Note that the rotary electric machine housing 4 and a housing 10 of the power conversion device 3 may be integrally molded. The rotary electric machine 2 is supplied with AC power from the power conversion device 3. The rotary electric machine 2 is controlled by the power conversion device 3.

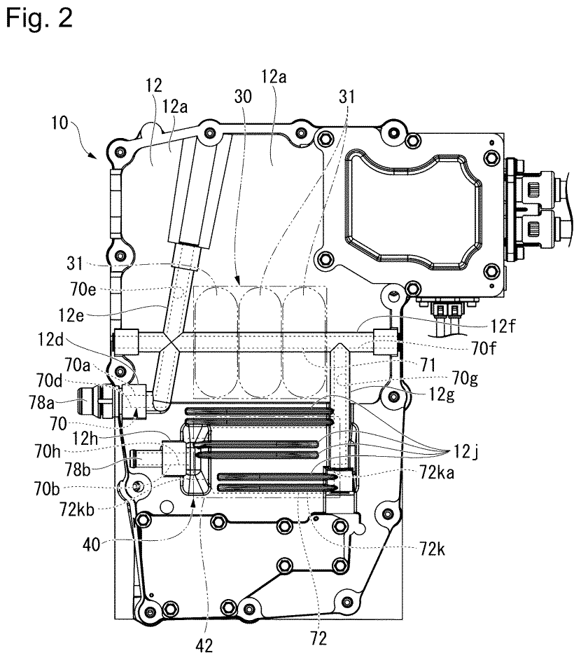

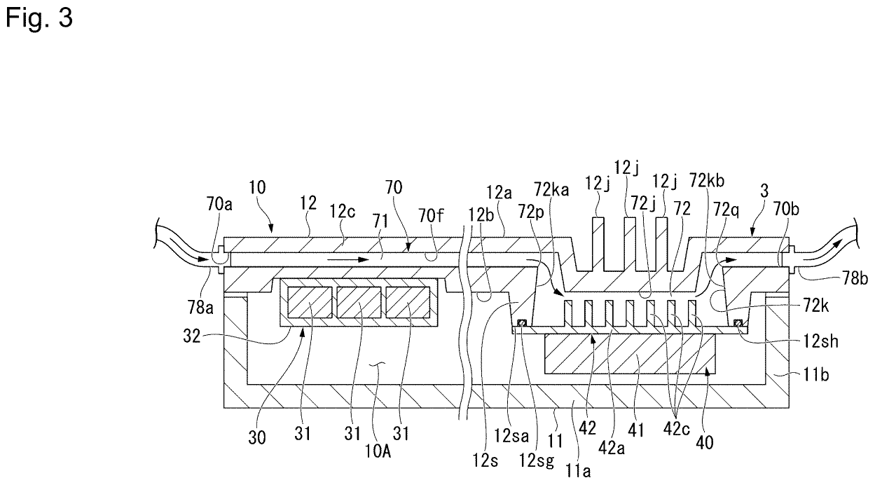

FIG. 2 is a plan view of the power conversion device 3. FIG. 3 is a schematic cross-sectional view of the power conversion device 3.

The power conversion device 3 of the present embodiment is an inverter device that converts DC power supplied from a battery (not illustrated) into AC power and supplies the AC power to the rotary electric machine 2.

As illustrated in FIG. 3, the power conversion device 3 includes a capacitor module (first module) 30, a power module (second module) 40, a housing 10, and a refrigerant flow path 70. Further, the power conversion device 3 may include a plurality of circuit boards (not illustrated) and the like

The housing 10 includes a housing body 11 and a lid 12. The housing body 11 and the lid 12 are made of, for example, an aluminum alloy, and are molded by casting such as die casting.

The housing body 11 opens upward. The upper opening of the housing body 11 is covered with the lid 12. The housing 10 has an accommodation space 10A surrounded by the housing body 11 and the lid 12. The accommodation space 10A accommodates the capacitor module 30 and the power module 40. The capacitor module 30 and the power module 40 are fixed to the lid 12 inside the accommodation space 10A.

The housing body 11 has a bottom wall 11a extending along a horizontal plane and a side wall 11b protruding upward from an outer edge of the bottom wall 11a. The bottom wall 11a is located below the accommodation space 10A. The side wall 11b surrounds the accommodation space 10A from the horizontal direction. The lid 12 is fixed to the upper end surface of the side wall 11b.

The lid 12 covers the accommodation space 10A from above. The lid 12 has a plate shape extending along a plane orthogonal to the up-down direction. In the following description, a direction along a plane orthogonal to the thickness direction of the lid 12 (horizontal direction of the present embodiment) is referred to as a plane direction of the lid 12.

The lid 12 is provided with the refrigerant flow path 70 through which a refrigerant flows. The refrigerant flow path 70 extends inside the lid 12 along a plane orthogonal to the up-down direction. That is, the refrigerant flow path 70 extends along the plane direction of the lid 12.

The refrigerant flowing through the refrigerant flow path 70 cools the power module 40 and the capacitor module 30 disposed in the accommodation space 10A. The refrigerant flow path 70 includes a first flow path portion 71 that cools the capacitor module 30 and a second flow path portion 72 that cools the power module 40. The first flow path portion 71 and the second flow path portion 72 will be described in detail later.

The refrigerant flow path 70 has an upstream end portion 70a and a downstream end portion 70b. In the following description, the arrangement of each part of the refrigerant flow path 70 will be described using the upstream side and the downstream side based on the flow direction of the refrigerant flowing through the refrigerant flow path 70. That is, the upstream end portion 70a is an end portion on the upstream side of the refrigerant flow path 70, and the downstream end portion 70b is an end portion on the downstream side of the refrigerant flow path 70. Connector portions 78a and 78b for connecting to pipes are attached to the upstream end portion 70a and the downstream end portion 70b, respectively.

A pipe (not illustrated) connected to a cooler (not illustrated) for cooling the refrigerant is connected to the connector portion 78a of the upstream end portion 70a. A pipe (not illustrated) connected to an oil cooler (not illustrated) below the power conversion device 3 is connected to the connector portion 78b of the downstream end portion 70b. The refrigerant exchanges heat with oil circulating in the rotary electric machine housing 4 in the oil cooler.

After being cooled by a cooler (not illustrated), the refrigerant of the present embodiment passes through the lid 12 to cool the power module 40 and the capacitor module 30, and further passes through an oil cooler to cool the oil. After following the above path, the refrigerant returns to the cooler again and circulates through the same path.

As illustrated in FIG. 3, the lid 12 has an outer surface 12a facing the opposite side of the accommodation space 10A and an inner surface 12b facing the accommodation space 10A side. In the present embodiment, the outer surface 12a faces upward, and the inner surface 12b faces downward.

The inner surface 12b is provided with a recess 72k and a pedestal portion 12s surrounding the periphery of the recess 72k. The recess 72k is recessed upward. Meanwhile, the pedestal portion 12s protrudes downward.

The recess 72k opens toward the accommodation space 10A side. The recess 72k accommodates at least a part of the power module 40. The recess 72k is disposed in the path of the refrigerant flow path 70.

As illustrated in FIG. 2, the recess 72k has a rectangular shape having a pair of short sides and a pair of long sides when viewed from the thickness direction of the lid 12. In the following description, a pair of inner surfaces respectively corresponding to a pair of short sides of the lid 12 is referred to as a first inner surface 72ka and a second inner surface 72kb.

As illustrated in FIG. 3, the first inner surface 72ka and the second inner surface 72kb face each other. The first inner surface 72ka is provided with a first opening portion 72p through which the refrigerant flows in. On the other hand, the second inner surface 72kb is provided with a second opening portion 72q through which the refrigerant flows out. The inner surface of the recess 72k has a bottom surface 72j facing the thickness direction (lower side in the present embodiment) of the lid 12. The refrigerant flows along the bottom surface 72j from the first opening portion 72p toward the second opening portion 72q inside the recess 72k.

The pedestal portion 12s has a pedestal surface 12sa facing downward. The pedestal surface 12sa is provided with a second recessed groove 12sg surrounding the periphery of the recess 72k. The second recessed groove 12sg opens downward. A second seal member 12sh is disposed in the second recessed groove 12sg.

As illustrated in FIG. 2, the lid 12 is provided with a plurality of holes 70d, 70e, 70f, 70g, and 70h. Each of the holes 70d, 70e, 70f, 70g, and 70h extends along the plane direction of the lid 12. Each of the holes 70d, 70e, 70f, 70g, and 70h has a circular cross-sectional shape and extends linearly. The holes 70d, 70e, 70f, 70g, and 70h are formed by drilling the lid 12.

The lid 12 of the present embodiment is provided with five holes 70d, 70e, 70f, 70g, and 70h. In the following description, the five holes are referred to as a first hole 70d, a second hole 70e, a third hole 70f, a fourth hole 70g, and a fifth hole 70h, respectively.

The upstream end portion 70a is disposed in the first hole 70d. That is, the upstream end portion 70a of the refrigerant flow path 70 is disposed in the first hole 70d. The first hole 70d intersects with the second hole 70e. As a result, the first hole 70d and the second hole 70e communicate with each other.

The second hole 70e extends in a direction inclined with respect to the first hole 70d. The second hole 70e intersects with the third hole 70f. As a result, the second hole 70e and the third hole 70f communicate with each other.

The third hole 70f extends in a direction inclined with respect to the second hole 70e. In the present embodiment, the extending direction of the third hole 70f is parallel to the extending direction of the first hole 70d. The third hole 70f intersects with the fourth hole 70g. As a result, the third hole 70f and the fourth hole 70g communicate with each other.

The fourth hole 70g is orthogonal to the third hole 70f. The fourth hole 70g opens at the first opening portion 72p of the first inner surface 72ka of the recess 72k.

The fifth hole 70h opens at the second opening portion 72q of the second inner surface 72kb of the recess 72k. The extending direction of the fifth hole 70h is parallel to the extending directions of the first hole 70d and the third hole 70f. The downstream end portion 70b is disposed in the fifth hole 70h.

The first hole 70d, the second hole 70e, the third hole 70f, the fourth hole 70g, the recess 72k, and the fifth hole 70h constitute the refrigerant flow path 70. The refrigerant flowing into the refrigerant flow path 70 from the upstream end portion 70a passes through the first hole 70d, the second hole 70e, the third hole 70f, the fourth hole 70g, the recess 72k, and the fifth hole 70h in this order.

In the present embodiment, the third hole 70f constitutes the first flow path portion 71. That is, the first flow path portion 71 is the third hole (hole) 70f provided in the lid 12. Therefore, the first flow path portion 71 of the present embodiment is one flow path extending linearly. Since the first flow path portion 71 of the present embodiment passes through the inside of the lid 12, the first flow path portion 71 is disposed outside the accommodation space 10A.

In the present embodiment, the second flow path portion 72 is provided inside the recess 72k. The second flow path portion 72 is provided in a space surrounded by the inner surface of the recess 72k and an element pedestal member (covering portion) 42 to be described later. Since the recess 72k opens into the accommodation space 10A, the second flow path portion 72 is disposed inside the accommodation space 10A.

The outer surface 12a of the lid 12 is provided with a plurality of protrusions 12d, 12e, 12f, 12g, and 12h. Each of the protrusions 12d, 12e, 12f, 12g, and 12h protrudes toward the outside of the accommodation space 10A. Each of the protrusions 12d, 12e, 12f, 12g, and 12h extends in a rib shape along the plane direction of the lid 12. Each of the protrusions 12d, 12e, 12f, 12g, and 12h has a semicircular cross-sectional shape.

The lid 12 of the present embodiment is provided with five protrusions 12d, 12e, 12f, 12g, and 12h. In the following description, the five protrusions are referred to as a first protrusion 12d, a second protrusion 12e, a third protrusion 12f, a fourth protrusion 12g, and a fifth protrusion 12h, respectively.

When viewed from the thickness direction of the lid 12, the first protrusion 12d overlaps the first hole 70d. The first hole 70d is disposed inside the first protrusion 12d. When viewed from the thickness direction of the lid 12, the second protrusion 12e overlaps the second hole 70e. The second hole 70e is disposed inside the second protrusion 12e. When viewed from the thickness direction of the lid 12, the third protrusion 12f overlaps the third hole 70f. The third hole 70f is disposed inside the third protrusion 12f. That is, the first flow path portion 71 is located inside the third protrusion (protrusion) 12f. When viewed from the thickness direction of the lid 12, the fourth protrusion 12g overlaps the fourth hole 70g. The fourth hole 70g is disposed inside the fourth protrusion 12g. When viewed from the thickness direction of the lid 12, the fifth protrusion 12h overlaps the fifth hole 70h. The fifth hole 70h is disposed inside the fifth protrusion 12h.

In the electromechanical drive device 1 for a vehicle in which the power conversion device 3 is integrated as in the present embodiment, when the dimension of the power conversion device 3 in the height direction increases, there is a risk that a boarding space in the vehicle is compressed. According to the present embodiment, the holes 70d, 70e, 70f, 70g, and 70h constituting the refrigerant flow path 70 are disposed inside the protrusions 12d, 12e, 12f, 12g, and 12h, respectively, so that the lid 12 at portions other than the protrusions can be thinned. As a result, it is possible to suppress the drive device 1 from compressing the boarding space in the vehicle. In addition, by thinning the lid 12, it is possible to reduce the weight of the power conversion device 3.

As illustrated in FIG. 2, the outer surface 12a of the lid 12 is provided with a plurality of fins 12j protruding toward the outside of the accommodation space 10A. In the present embodiment, the outer surface 12a is provided with six fins 12j. At least a part (five fins 12j in the present embodiment) of the plurality of fins 12j overlaps the second flow path portion 72 when viewed from the thickness direction of the lid 12. According to the fin 12j of the present embodiment, the fin 12j can increase the surface area of the outer surface 12a of the lid 12 to cool the refrigerant flowing through the second flow path portion 72.

In the present embodiment, the case where the plurality of fins 12j are provided on the outer surface 12a of the lid 12 has been described, but the number of fins 12j provided on the lid 12 is not limited to the present embodiment, and may be, for example, one.

As illustrated in FIG. 3, the capacitor module 30 includes a plurality of (three in the present embodiment) capacitor elements (heat generating elements) 31 and a capacitor case 32. The capacitor case 32 accommodates the plurality of capacitor elements 31.

The capacitor case 32 is fixed to the inner surface 12b of the lid 12 of the housing 10. The capacitor case 32 is made of an insulating resin material. The capacitor case 32 surrounds a wiring member (not shown) and the like of the capacitor module 30 from the outer periphery. The capacitor case 32 ensures insulation between the capacitor module 30 and the housing 10. The capacitor case 32 may have a heat transfer plate for uniformly cooling the whole of the plurality of accommodated capacitor elements 31. In this case, the heat transfer plate is disposed so as to surround the plurality of capacitor elements 31 and to be in contact with the inner surface 12b of the lid body 12.

The capacitor element 31 is disposed in a path that connects the power module 40 and the battery and supplies power to the power module 40. The capacitor element 31 of the present embodiment is an X capacitor that smooths a DC voltage supplied to the power module 40. The capacitor element 31 is a heat generating element. The capacitor element 31 is cooled by the refrigerant.

Note that the configuration of the capacitor module 30 of the present embodiment is an example, and the present invention is not limited thereto. The capacitor element 31 may have another function such as a Y capacitor for removing switching noise of the power module 40. The capacitor module 30 may include several types of capacitor elements having different functions.

As illustrated in FIG. 3, the capacitor module 30 is in contact with the inner surface 12b of the lid 12. As illustrated in FIG. 2, the capacitor module 30 overlaps the third hole 70f when viewed from the thickness direction of the lid 12. That is, the capacitor module 30 is in contact with the lid 12 and overlaps the first flow path portion 71 of the refrigerant flow path 70 when viewed from the thickness direction of the lid 12. The refrigerant flowing through the first flow path portion 71 cools the capacitor module 30 via the lid 12.

As illustrated in FIG. 2, in the present embodiment, the plurality of capacitor elements 31 are arranged side by side along the direction in which the first flow path portion 71 extends. As described above, by arranging the plurality of capacitor elements 31 linearly, it is possible to effectively cool all the capacitor elements 31 by the first flow path portion 71 extending linearly. That is, according to the present embodiment, the plurality of capacitor elements 31 can be uniformly cooled while the first flow path portion 71 has a simple shape.

Such an effect is more remarkable when the capacitor module 30 includes three or more capacitor elements 31 as shown in the present embodiment. That is, by linearly arranging three or more capacitor elements 31, three or more capacitor elements 31 can be uniformly cooled by the linear first flow path portion 71 that is not bent.

As illustrated in FIG. 3, the power module 40 includes a switching element 41 and an element pedestal member (covering portion) 42. The element pedestal member 42 serves as a pedestal for fixing the switching element 41.

The power module 40 is disposed along the lid 12 of the housing 10. The power module 40 and the capacitor module 30 are arranged side by side along the plane direction of the lid 12. That is, the power module 40 and the capacitor module 30 are disposed adjacent to each other without overlapping each other when viewed from the thickness direction of the lid 12. According to the present embodiment, since the power module 40 and the capacitor module 30 are arranged side by side along the plane direction of the lid 12, the power conversion device 3 can be downsized in the thickness direction of the lid 12.

The switching element 41 of the present embodiment is an insulated gate bipolar transistor (IGBT). The switching element 41 is a heat generating element. The switching element 41 generates a larger calorific value than the capacitor element 31. The switching element 41 is cooled by the refrigerant.

The element pedestal member 42 is made of a metal material having high heat conductivity. Examples of a material constituting the element pedestal member 42 include an aluminum alloy and a copper alloy. The element pedestal member 42 functions as the element pedestal member 42 that transfers heat from the switching element 41 to the refrigerant.

The element pedestal member 42 holds the switching element 41. The element pedestal member 42 includes a plate-shaped cover body 42a and a plurality of heat dissipation pins 42c protruding upward from an upper surface of the cover body 42a. The lower surface of the cover body 42a is in contact with and fixed to the switching element 41. The element pedestal member 42 may have a heat dissipation fin instead of the heat dissipation pin 42c.

The upper surface of the cover body 42a covers the recess 72k. The upper surface of the cover body 42a faces the pedestal surface 12sa in the up-down direction. The second seal member 12sh is sandwiched between the upper surface of the cover body 42a and the bottom surface of the second recessed groove 12sg provided in the pedestal surface 12sa. As a result, the region disposed inside the second seal member 12sh as viewed from the thickness direction of the lid 12 is sealed, and leakage of the refrigerant is suppressed.

The plurality of heat dissipation pins 42c are disposed inside the recess 72k. The first inner surface 72ka of the recess 72k is provided with the first opening portion 72p through which the refrigerant flows into the recess 72k. The refrigerant flowing into the recess 72k flows through a gap between the plurality of heat dissipation pins 42c between the bottom surface 72j of the recess 72k and the upper surface of the cover body 42a. The space between the inner wall of the recess 72k and the upper surface of the cover body 42a constitutes the second flow path portion 72. The refrigerant in the recess 72k flows out from the second opening portion 72q provided on the second inner surface 72kb of the recess 72k.

According to the present embodiment, the second flow path portion 72 is provided in a space surrounded by the inner wall of the recess 72k and the element pedestal member (covering portion) 42 covering the recess 72k. The element pedestal member 42 is a part of the power module 40. Therefore, the refrigerant flowing through the second flow path portion 72 flows between the inner wall surface of the recess 72k and the element pedestal member 42. That is, the refrigerant is cooled by being in direct contact with the power module 40. Further, the element pedestal member 42 cools the switching element. As a result, the refrigerant quickly and efficiently cools the power module 40.

According to the present embodiment, the element pedestal member 42 includes the plurality of heat dissipation pins 42c (or heat dissipation fins) disposed in the recess 72k. The refrigerant passes between the plurality of heat dissipation pins 42c. Therefore, a large contact area between the element pedestal member 42 and the refrigerant can be secured, and the element pedestal member 42 can be efficiently cooled by the refrigerant.

The refrigerant flow path 70 of the present embodiment includes the first flow path portion 71 that cools the capacitor module 30 and the second flow path portion 72 that cools the power module 40. In addition, the first flow path portion 71 is disposed outside the accommodation space 10A, and the second flow path portion 72 is disposed inside the accommodation space 10A.

The capacitor module 30 and the power module 40 of the present embodiment are both heating elements. In addition, the power module 40 generates a larger calorific value than the capacitor module 30. According to the present embodiment, the power module 40 having a large calorific value is efficiently cooled by being brought into direct contact with the refrigerant in the second flow path portion 72 flowing in the accommodation space 10A. However, the second flow path portion 72 requires a sealing structure in order to pass through the inside of the accommodation space 10A, and the flow path structure becomes complicated and the manufacturing cost of the power conversion device 3 increases.

The capacitor module 30 of the present embodiment is cooled by the refrigerant passing through the first flow path portion 71 disposed outside the accommodation space 10A. The capacitor module 30 has a smaller calorific value than the power module 40. Therefore, even when the cooling is performed by the first flow path portion 71 that does not bring the refrigerant into direct contact, the capacitor module 30 can be sufficiently cooled. The cooling structure for cooling the capacitor module 30 can be simplified, and the structural cost of the power conversion device 3 can be reduced.

That is, according to the present embodiment, by adopting a flow path structure corresponding to each calorific value for a plurality of modules (the capacitor module 30 and the power module 40) which are heating elements, efficient cooling can be performed while suppressing the overall manufacturing cost.

According to the present embodiment, the second flow path portion 72 is disposed on the downstream side of the first flow path portion 71. Therefore, the refrigerant cooled in the cooler (not illustrated) cools the capacitor module 30 having a small calorific value in the first flow path portion 71, and then cools the power module 40 having a large calorific value in the second flow path portion 72. According to the present embodiment, in the first flow path portion 71 and the second flow path portion 72, the refrigerant having an appropriate temperature can flow according to the calorific values of the capacitor module 30 and the power module 40 to be cooled, and each module can be efficiently cooled as the entire refrigerant flow path 70.

Although the embodiment of the present invention has been described above, the respective configurations in the embodiment and combinations thereof are merely examples, and addition, omission, substitution, and other changes of the configurations can be appropriately made within a range not departing from the gist of the present invention. Also note that the present invention is not limited by the embodiment.

For example, in the above-described embodiment, the case where the module (first module) having a relatively small calorific value is the capacitor module 30, and the module (second module) having a relatively large calorific value is the power module 40 has been described. However, the modules to be cooled in the power conversion device 3 are not limited to the capacitor module 30 and the power module 40.

In the above-described embodiment, the case where the power conversion device 3 is an inverter device that converts DC power into AC power has been described. However, the power conversion device may be a converter that converts AC power into DC power.

Although the first flow path portion of the above-described embodiment is a hole provided in the lid, the first flow path portion may have another configuration. The first flow path portion only has to be disposed outside the accommodation space of the housing, and may be, for example, a pipe of another member disposed so as to be in contact with the outer surface of the lid.

Note that the present technique can have the following configurations.
(1) A power conversion device including: a first module that is a heating element; a second module that is a heating element having a larger calorific value than the first module; a housing having an accommodation space in which the first module and the second module are accommodated; and a refrigerant flow path through which a refrigerant flows, in which the housing includes a lid that covers the accommodation space, and the refrigerant flow path includes: a first flow path portion that is disposed outside the accommodation space and cools the first module via the lid; and a second flow path portion that is disposed inside the accommodation space and cools the second module.
(2) The power conversion device according to (1), in which the first flow path portion is a hole provided in the lid, and the first module is in contact with the lid and overlaps the first flow path portion when viewed from a thickness direction of the lid.
(3) The power conversion device according to (2), in which the lid has an outer surface facing an opposite side of the accommodation space, the outer surface is provided with a protrusion protruding toward an outside of the accommodation space, and the first flow path portion is located inside the protrusion.
(4) The power conversion device according to any one of (1) to (3), in which the first flow path portion is one flow path extending linearly, the first module includes a plurality of heat generating elements, and a plurality of the heat generating elements are arranged side by side along a direction in which the first flow path portion extends.
(5) The power conversion device according to any one of (1) to (4), in which the lid has an inner surface facing the accommodation space side, the inner surface is provided with a recess, the second flow path portion is provided in a space surrounded by an inner wall of the recess and a covering portion covering the recess, and the covering portion is a part of the second module.
(6) The power conversion device according to any one of (1) to (5), in which the lid has an outer surface facing an opposite side of the accommodation space, the outer surface is provided with a fin protruding toward an outside of the accommodation space, and the fin overlaps the second flow path portion when viewed from a thickness direction of the lid.
(7) The power conversion device according to any one of (1) to (6), in which the second flow path portion is disposed on a downstream side of the first flow path portion.
(8) The power conversion device according to any one of (1) to (7), in which the first module is a capacitor module, and the second module is a power module.
(9) A drive device including: the power conversion device according to any one of (1) to (8); and a rotary electric machine connected to the power conversion device.

Features of the above-described preferred embodiments and the modifications thereof may be combined appropriately as long as no conflict arises.

While preferred embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

1. A power conversion device comprising:
a first module that is a heating element;
a second module that is a heating element having a larger calorific value than the first module;
a housing having an accommodation space in which the first module and the second module are accommodated; and
a refrigerant flow path through which a refrigerant flows,
wherein the housing includes a lid that covers the accommodation space, and
the refrigerant flow path includes:
a first flow path portion that is disposed outside the accommodation space and cools the first module via the lid; and
a second flow path portion that is disposed inside the accommodation space and cools the second module.

2. The power conversion device according to claim 1, wherein
the first flow path portion is a hole provided in the lid, and
the first module is in contact with the lid and overlaps the first flow path portion when viewed from a thickness direction of the lid.

3. The power conversion device according to claim 2, wherein
the lid has an outer surface facing an opposite side of the accommodation space,
the outer surface is provided with a protrusion protruding toward an outside of the accommodation space, and
the first flow path portion is located inside the protrusion.

4. The power conversion device according to claim 1, wherein
the first flow path portion is one flow path extending linearly,
the first module includes a plurality of heat generating elements, and
a plurality of the heat generating elements are arranged side by side along a direction in which the first flow path portion extends.

5. The power conversion device according to claim 1, wherein
the lid has an inner surface facing the accommodation space side,
the inner surface is provided with a recess,
the second flow path portion is provided in a space surrounded by an inner wall of the recess and a covering portion covering the recess, and
the covering portion is a part of the second module.

6. The power conversion device according to claim 1, wherein
the lid has an outer surface facing an opposite side of the accommodation space,
the outer surface is provided with a fin protruding toward an outside of the accommodation space, and
the fin overlaps the second flow path portion when viewed from a thickness direction of the lid.

7. The power conversion device according to claim 1, wherein the second flow path portion is disposed on a downstream side of the first flow path portion.

8. The power conversion device according to claim 1, wherein
the first module is a capacitor module, and
the second module is a power module.

9. A drive device comprising:
the power conversion device according to claim 1; and
a rotary electric machine connected to the power conversion device.
